(19) United States
(12) Patent Application Publication
(10) Pub. No.: US 2016/0377652 A1
(43) Pub. Date: Dec. 29, 2016

(54) SEMICONDUCTOR DEVICE MANUFACTURING METHOD

(71) Applicant: Renesas Electronics Corporation, Tokyo (JP)

(72) Inventors: Seiki INOUE, Gunma (JP); Tomoharu TAKAHASHI, Gunma (JP)

(21) Appl. No.: 15/098,163

(22) Filed: Apr. 13, 2016

(30) Foreign Application Priority Data
Jun. 23, 2015 (JP) 2015-126034

(51) Int. Cl. G01R 1/04; G01R 31/26

(52) U.S. Cl. CPC G01R 1/0458; G01R 31/2601

(57) ABSTRACT

A semiconductor device manufacturing method which enables high quality semiconductor device testing. The method includes the following steps : providing a test board in which a plurality of IC sockets mounted on the front surface and a plurality of surface mount relay sockets to be electrically coupled to the IC sockets are mounted on the back surface; and placing semiconductor devices in the IC sockets and performing a test on the semiconductor devices with relays attached to the relay sockets. The IC socket and the test board are electrically coupled by a plurality of coupling terminals provided in an area for the IC socket in a plan view, and some of the electronic component sockets are mounted in a manner to overlap some of the IC sockets in a plan view.

### CROSS-REFERENCE TO RELATED APPLICATIONS

The disclosure of Japanese Patent Application No. 2015-126034 filed on Jun. 23, 2015 including the specification, drawings and abstract is incorporated herein by reference in its entirety.

### BACKGROUND

The present invention relates to semiconductor device manufacturing methods and more particularly to a semiconductor device manufacturing technique which uses a test board with relay sockets mounted on its back surface.

As the sophistication (multiple output, high output) of semiconductor devices and testers progresses, it becomes necessary to mount a plurality of relay sockets on a test board to measure a plurality of semiconductor devices at a time.

In the test board, the area where components can be mounted is physically limited. Various measures, including the use of a larger test board, have been taken in order to increase the area where components can be mounted. However, if a larger test board is used, components must be divided into two groups: components which can be located near the device to be tested (semiconductor device) and components which are compelled to be located away from the device to be tested.

In order to minimize the influence of the measuring system for testing the device, which must meet the requirements for high speed and high sensitivity, components should be located as near the device as possible and the wiring resistance and wiring capacitance should be decreased.

On the other hand, the number of devices which are tested at a time tends to increase and thus the number of components to be mounted tends to increase, though the component mounting area which satisfies the demand is limited.

For example, Japanese Unexamined Patent Application Publication No. Hei 5 (1993)-157805 discloses a semiconductor device measuring device which makes measurements using a socket board bearing sockets for housing semiconductor devices. Also, Japanese Unexamined Patent Application Publication No. Hei 11 (1999)-23648 discloses the structure of a test head which uses a DUT (Device Under Test) board bearing an IC socket to test a semiconductor device.

### SUMMARY

Since a relay socket mounted on the above test board is a lead type socket, when the relay socket is mounted on the front surface of the test board, the lead of the relay socket protrudes down to the back surface of the test board. If so, the space available for mounting relays on the back surface may be insufficient.

Furthermore, in this case, some of the relay sockets are compelled to be located in a peripheral area of the test board, which results in an increase in the wiring length and thereby causes a voltage drop during measurement.

The above and further objects and novel features of the invention will more fully appear from the following detailed description in this specification and the accompanying drawings.

According to one aspect of the present invention, there is provided a semiconductor device manufacturing method which includes the step (a) of providing a test board having a first surface and a second surface, in which a plurality of IC sockets are mounted on the first surface and a plurality of surface mount electronic component sockets to be electrically coupled to the IC sockets are mounted on the second surface. The method further includes the step (b) of placing semiconductor devices in the IC sockets and performing a test on the semiconductor devices with electronic components attached to the electronic component sockets. The IC socket and the test board are electrically coupled by a plurality of coupling terminals provided in an area for the IC socket in a plan view, and some of the electronic component sockets are mounted in a manner to overlap some of the IC sockets in a plan view.

According to another aspect of the present invention, there is provided a semiconductor device manufacturing method which includes the step (a) of providing a test board having a first surface and a second surface, in which a plurality of IC sockets are mounted on the first surface and a plurality of surface mount electronic component sockets to be electrically coupled to the IC sockets via through-hole wirings are mounted on the second surface. The method further includes the step (b) of placing semiconductor devices in the IC sockets and performing a test on the semiconductor devices with electronic components attached to the electronic component sockets. The IC socket and the test board are electrically coupled by a plurality of coupling terminals provided in an area for the IC socket in a plan view and some of the electronic component sockets are mounted in a manner to overlap some of the IC sockets in a plan view. Furthermore, a land electrically coupled to the through-hole wiring is formed away from the through-hole wiring on the second surface in a plan view, and the electronic component socket mounted in a manner to overlap some of the IC sockets in a plan view is electrically coupled to the land.

According to the present invention, the length of the wiring for coupling an IC socket and an electronic component socket can be shortened so that high quality semiconductor device testing can be performed.

### BRIEF DESCRIPTION OF THE DRAWINGS

FIG. 1 is a perspective view showing an example of the structure of a test board according to a first embodiment;

FIG. 2 is a plan view showing an example of the structure of the test board shown in FIG. 1;

FIG. 3 is a back view showing an example of the structure of the test board shown in FIG. 1;

FIG. 4 is a side view showing an example of the structure of the test board shown in FIG. 1;

FIG. 5 is a side view with an enlarged fragmentary view, showing an example of the coupling structure between the test board shown in FIG. 1 and an IC socket;

FIG. 6 is a sectional view showing an example of the coupling structure between through-hole wirings of the test board shown in FIG. 1 and the IC socket;

FIG. 7 is a comparison table which shows the relay and surface-mount relay socket mounted on the test board according to the first embodiment with lead type relay sockets in a comparative example;

FIG. 8 is a side view with an enlarged sectional view, showing the mounting structure of the lead type relay socket and the IC socket coupling structure in the test board in the comparative example;

FIG. 9 is a back view showing the relay arrangement of the test board in the comparative example;

FIG. 10 is a waveform chart showing the electrical characteristics of a signal pin of the test board in the comparative example;

FIG. 11 is a back view of the relay arrangement of the test board according to the first embodiment;

FIG. 12 is a waveform chart showing the electrical characteristics of the signal pin of the test board shown in FIG. 11;

FIG. 13 is a back view illustrating an image of the wiring length of the test board in the comparative example;

FIG. 14 is a back view illustrating an image of the wiring length of the test board in the comparative example;

FIG. 15 is a back view illustrating an image of the wiring length of the test board according to the first embodiment;

FIG. 16 is a sectional view showing an image of the wiring length of the test board in the comparative example which uses inner wirings;

FIG. 17 is a plan view showing an image of the wiring length of the test board in the comparative example which uses inner wirings;

FIG. 18 is a sectional view showing an image of the wiring length of the test board according to the first embodiment which uses inner wirings;

FIG. 19 is a plan view showing an image of the wiring length of the test board according to the first embodiment which uses inner wirings;

FIG. 20 is a back view of the test board as a variation of the first embodiment, showing the arrangement of relays;

FIG. 21 is a sectional view showing how a relay socket is mounted in the comparative example;

FIG. 22 is a sectional view showing how the relay socket in the comparative example receives an impact;

FIG. 23 is a sectional view showing the relay socket in the comparative example which cannot be repaired,

FIG. 24 is a sectional view with a back view showing the form of a land of the test board in the comparative example;

FIG. 25 is a sectional view showing how a relay socket is mounted in a second embodiment;

FIG. 26 is a sectional view showing how the relay socket in the second embodiment receives an impact;

FIG. 27 is a sectional view showing how the relay socket in the second embodiment is repaired; and

FIG. 28 is a sectional view with a back view, showing the form of a land of the test board in the second embodiment.

### DETAILED DESCRIPTION

As for the preferred embodiments of the invention as described below, basically the same or similar elements or matters will not be repeatedly described except when necessary.

The preferred embodiments of the present invention may be described in different sections or separately as necessary or for the sake of convenience, but the embodiments described as such are not irrelevant to each other unless otherwise expressly stated. One embodiment may be, in whole or in part, a modified, detailed or supplementary form of another.

In the preferred embodiments as described below, when numerical information for an element (the number of pieces, numerical value, quantity, range, etc.) is indicated by a specific number, it is not limited to the specific number unless otherwise specified or theoretically limited to that number; it may be larger or smaller than the specific number.

In the preferred embodiments as described below, constituent elements (including constituent steps) are not necessarily essential unless otherwise specified or theoretically essential.

In the preferred embodiments as described below, as for constituent elements, it is obvious that the expression “comprising A”, “comprised of A”, “having A”, or “including A” does not exclude another element unless exclusion of another element is expressly stated. Similarly, in the preferred embodiments as described below, when a specific form or positional relation is indicated for an element, it should be interpreted to include a form or positional relation which is virtually equivalent or similar to the specific form or positional relation unless otherwise specified or theoretically limited to the specific form or positional relation. The same is true for the above numerical values and ranges.

Next, the preferred embodiments of the invention will be described in detail referring to the accompanying drawings. In all the drawings that illustrate the preferred embodiments, members with like functions are designated by like reference numerals and repeated descriptions thereof are omitted. For easy understanding, hatching may be used even in a plan view.

### First Embodiment

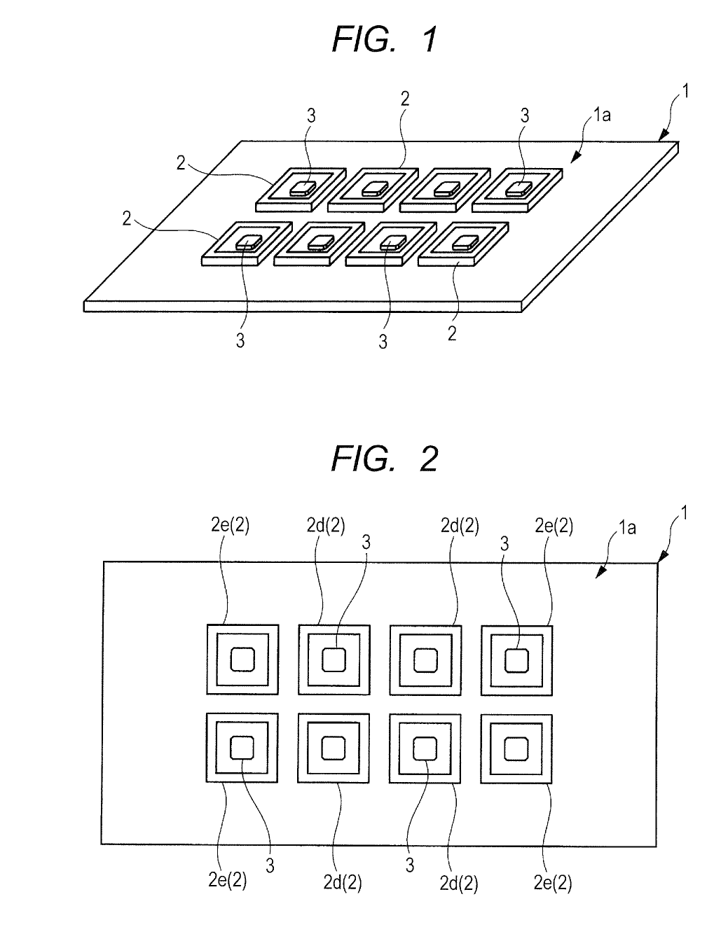

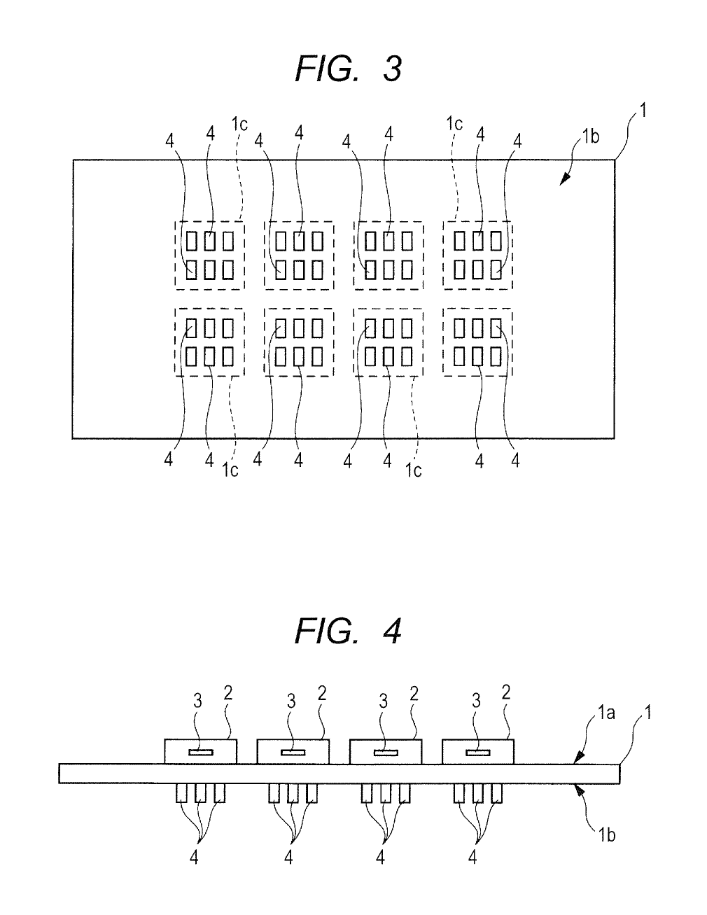

FIG. 1 is a perspective view showing an example of the structure of a test board according to the first embodiment; FIG. 2 is a plan view showing an example of the structure of the test board shown in FIG. 1; FIG. 3 is a back view showing an example of the structure of the test board shown in FIG. 1; and FIG. 4 is a side view showing an example of the structure of the test board shown in FIG. 1.

Next, the structure of the test board 1 according to the first embodiment will be described. As shown in FIGS. 1 to 4, the test board 1 has a front surface (first surface, upper surface) 1a and a back surface (second surface, lower surface) 1b opposite to the front surface 1a. A plurality of IC (Integrated Circuit) sockets 2 are mounted on the front surface 1a and a plurality of surface-mount relay sockets (electronic component sockets) 4 are mounted on the back surface 1b.

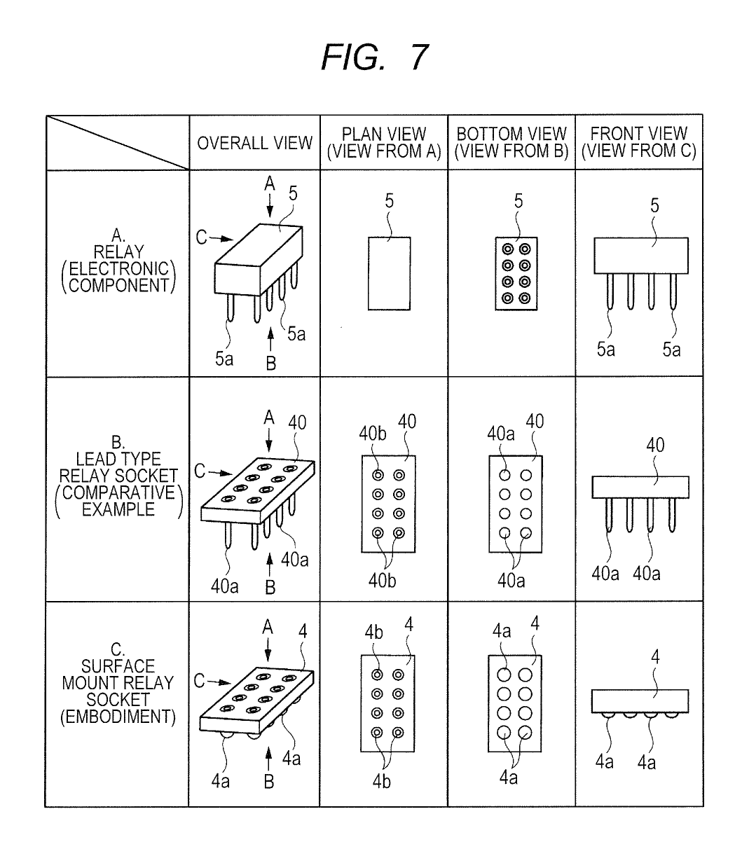

The IC sockets 2 and the relay sockets 4 are electrically coupled. While a semiconductor device (DUT) 3 as the device to be tested is attached to each of the IC sockets 2 and a relay (electronic component) 5 shown in FIG. 7 is attached to each of the relay sockets 4, an electric test is performed on the semiconductor device 3 at the testing step.

As shown in FIGS. 1 and 2, eight IC sockets 2 are arranged in a matrix pattern of 2 (rows) by 4 (columns) on the front surface 1a of the test board 1 according to the first embodiment.

On the test board 1, several relay sockets 4 mounted on the back surface 1b are arranged in a manner to overlap one of the IC sockets 2 in a plan view.

Specifically, the back surface 1b of the test board 1 shown in FIG. 3 has eight under-IC-socket areas 1c which correspond to the eight IC sockets 2 mounted on the front surface 1a of the test board 1 as shown in FIG. 2 and several relay sockets 4 are mounted in each of the eight under-IC-socket areas 1c. In short, each of the relay sockets 4 is mounted in a manner to overlap one of the IC sockets 2 in a plan view.

In the structure shown in FIGS. 3 and 4, six relay sockets 4 are mounted in each of the eight under-IC-socket areas 1c.

Next, the coupling structure between the test board 1 and an IC socket 2 and the coupling structure between the test board 1 and a relay socket 4 will be described.

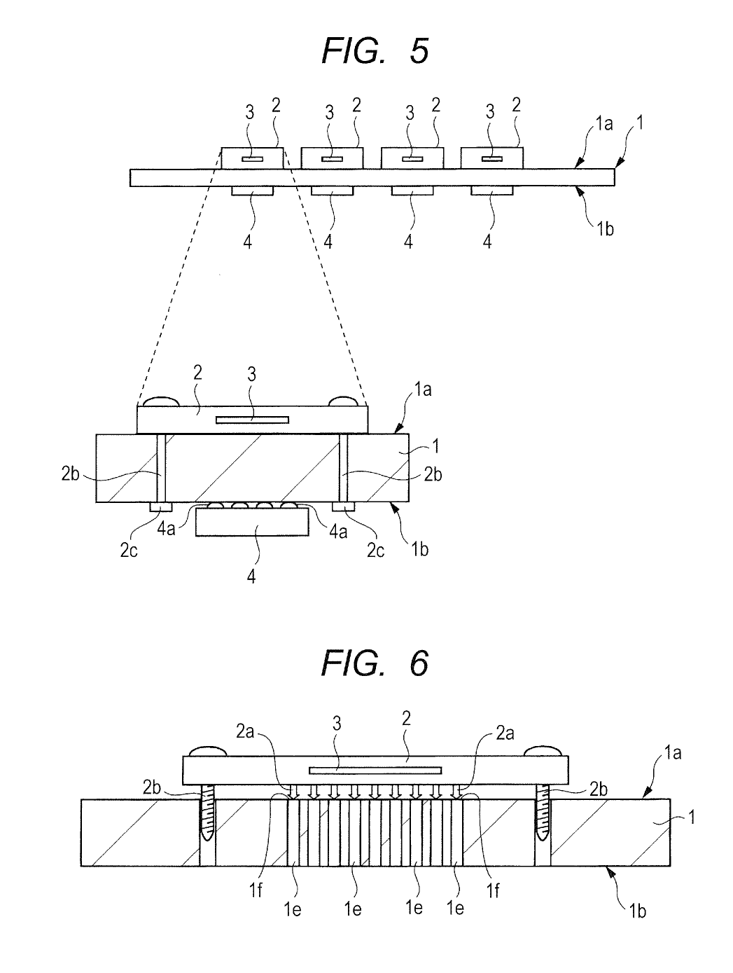

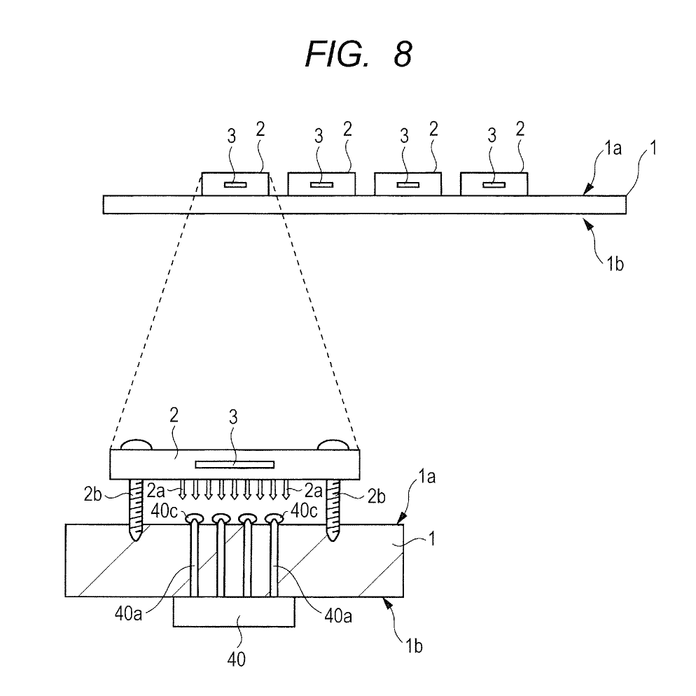

FIG. 5 is a side view with an enlarged fragmentary view, showing an example of the coupling structure between the test board shown in FIG. 1 and an IC socket and FIG. 6 is a sectional view showing an example of the coupling structure between through-hole wirings of the test board shown in FIG. 1 and the IC socket. FIG. 7 is a comparison table which shows the relay and surface-mount relay socket mounted on the test board according to the first embodiment and the lead type relay socket in a comparative example and FIG. 8 is a side view with an enlarged sectional view, showing the mounting structure of the lead type relay socket and the IC socket coupling structure in the test board in the comparative example.

As shown in FIGS. 5 and 6, the IC sockets 2 and the test board 1 are electrically coupled by a plurality of coupling terminals provided in the areas for the IC sockets 2 in a plan view. The relay sockets 4 used in the first embodiment are of the surface mount type as shown in FIG. 5. In other words, each relay socket 4 mounted on the back surface 1b of the test board 1 does not have any part protruding from the back surface 1b. For example, the relay sockets 4 shown in FIG. 5 are coupled to terminals of the test board 1 on the back surface 1b of the test board 1 by soldering.

Next, the surface mount relay socket 4 used in the first embodiment will be described referring to FIG. 7.

Row A of the table of FIG. 7 shows a relay 5 as an example of an electronic component. The relay 5 has a plurality of lead parts 5a as external terminals. Row B of the table shows a relay socket 40 to which the relay 5 is attached, as a socket in the comparative example. The relay socket 40 in the comparative example is a lead type socket with a plurality of leads 40a. The lead parts 5a of the relay 5 are fitted into coupling parts 40b of the relay socket 40 so that the relay 5 is held and electrically coupled to the relay socket 40.

As shown in the enlarged view of FIG. 8, in the case of the relay socket 40 in the comparative example, the leads 40a are inserted from the back surface 1b of the test board 1 and exposed on the front surface 1a and then the leads 40a are fixed on the test board 1 by solder 40c. Therefore, when the lead type relay socket 40 is attached to the back surface 1b of the test board 1, contact (coupling by the coupling terminals 2a in the IC socket 2 area) is not made between the IC socket 2 and the test board 1.

Therefore, when the lead type relay socket 40 is used, the relay socket 40 cannot be mounted on the back surface 1b just under the IC socket 2.

On the other hand, the surface-mount relay socket 4 used in the first embodiment is shown in Row C of the table of FIG. 7.

The surface mount relay socket 4 includes a plurality of bump electrodes 4a as external terminals (electrodes) and like the relay socket 40, the lead parts 5a of the relay 5 are fitted into coupling parts 4b of the relay socket 4 so that the relay 5 is held and electrically coupled to the relay socket 4.

As illustrated in the enlarged view of FIG. 5, since the relay socket 4 is a surface mount socket with bump electrodes 4a, it can be coupled to the test board 1 by soldering the bump electrodes 4a onto only the back surface 1b of the test board 1.

Consequently, the IC socket 2 and the test board 1 can be electrically coupled by the several coupling terminals located in the area for the IC socket 2 in a plan view. Specifically, as shown in FIG. 6, pogo seats (coupling terminals) 1f of the through-hole wirings 1e of the test board 1 can be electrically coupled to a plurality of pogo pins (coupling terminals) 2a of the IC socket 2 in the area for the IC socket 2 in a plan view.

Therefore, when the surface mount relay socket 4 is used, the relay socket 4 can be mounted on the back surface 1b just under the IC socket 2 as shown in FIG. 5 so that a plurality of IC sockets 2 are electrically coupled to a plurality of relay sockets 4 via the through-hole wirings 1e of the test board 1 as shown in FIG. 6.

As shown in FIG. 5, the IC sockets 2 are each mounted on the test board 1 in an attachable/detachable manner. For example, they are attached detachably using screws 2b and nuts 2c. Therefore, the IC sockets 2 can be cleaned or replaced and the maintainability of the IC sockets 2 is improved.

As mentioned above, the use of the surface mount relay socket 4 makes it possible to mount the relay socket 4 on the back surface 1b just under the IC socket 2 on the front surface 1a by soldering. Specifically, some of the relay sockets 4 are mounted in a manner to overlap one of the IC sockets 2 in a plan view.

Next, the method for manufacturing (testing or measuring) a semiconductor device according to the first embodiment will be described.

First, a test board 1 is provided in which a plurality of IC sockets are mounted on the front surface 1a, a plurality of surface mount relay sockets 4 to be electrically coupled to the IC sockets are mounted on the back surface 1b, and a plurality of relay sockets 4 are mounted in a manner to overlap any of the IC sockets 2 in a plan view. In short, a test board 1 in which a plurality of surface mount relay sockets 4 are mounted in the under-IC-socket areas 1c of the back surface 1b is provided.

The IC socket 2 and the test board 1 are electrically coupled by a plurality of coupling terminals provided in the area for the IC socket 2 in a plan view. The coupling terminals are pogo pins 2a of the IC socket 2 and pogo seats 1f at the ends of a plurality of through-hole wirings 1e in the test board 1.

After providing the test board, a semiconductor device 3 is placed in each of the IC sockets 2, a relay 5 is attached to each of the relay sockets 4 and the semiconductor device 3 is tested (measured).

Next, the effect of the use of the surface mount relay socket 4 in the first embodiment will be described in comparison with the lead type relay socket 40 in the comparative example.

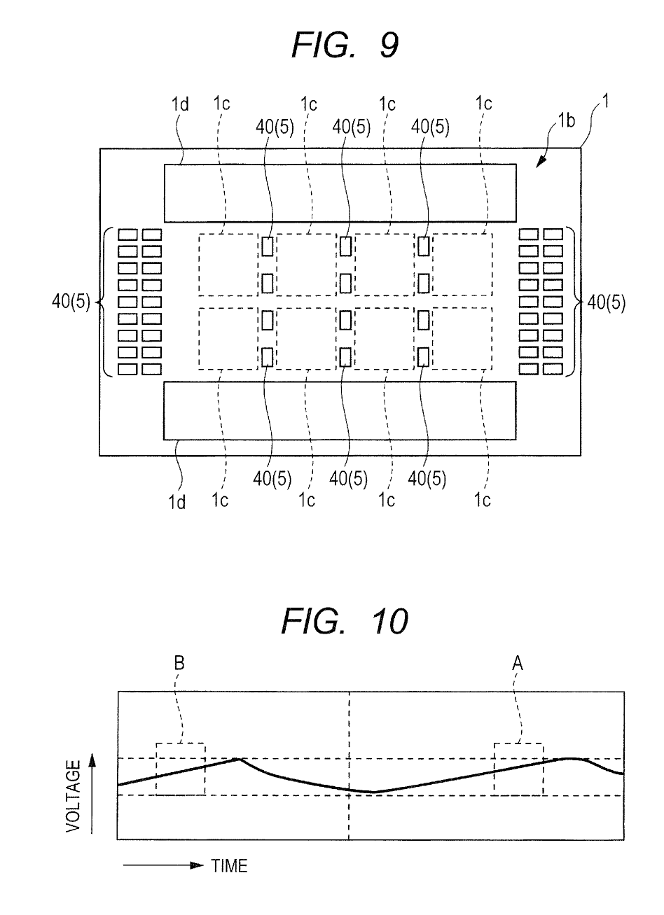

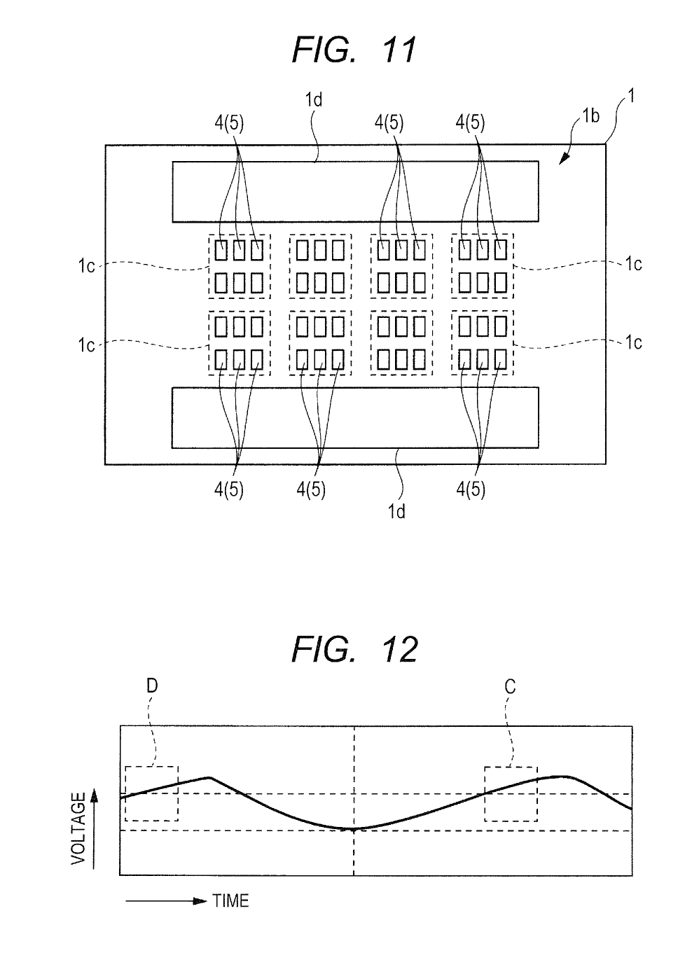

FIG. 9 is a back view showing the relay arrangement of the test board in the comparative example; FIG. 10 is a waveform chart showing the electrical characteristics of a signal pin of the test board in the comparative example; FIG. 11 is a back view showing the relay arrangement of the test board according to the first embodiment; and FIG. 12 is a waveform chart showing the electrical characteristics of the signal pin of the test board shown in FIG. 11.

In the case of the test board 1 in the comparative example shown in FIG. 9, since the lead type relay sockets 40 are used, the relay sockets 40 cannot be located in the under-IC-socket areas 1c of the back surface 1b of the test board 1. Therefore, most of the relay sockets 40 are located in peripheral areas of the test board 1 away from the under-IC-socket areas 1c and the component mounting prohibition areas 1d. Since the relay sockets 40 are located remotely from the IC sockets 2, the wiring for coupling an IC socket 2 and a relay socket 40 is long.

Consequently, as shown in the waveform chart of FIG. 10 for the signal pin in the comparative example, there arises a problem that the voltage does not rise up to the expected level in regions A and B of the chart. Specifically, due to the increased wiring length, the wiring resistance and wiring capacitance are added and the voltage does not rise up to the expected level and so, in the case of a multiple parallel test board 1 on which a larger number of electronic components such as relays are mounted, its existing characteristics cannot be maintained.

On the other hand, in the test board 1 according to the first embodiment as shown in FIG. 11, the surface mount relay sockets 4 are used and thus a relay socket 4 can be located in an under-IC-socket area 1c of the back surface 1b of the test board 1. In the example shown in FIG. 11, six relay sockets 4 are located in each of eight under-IC-socket areas 1c.

This means that every relay socket 4 is located in an under-IC-socket area 1c. In other words, every relay socket 4 is mounted just under an IC socket without protruding from an under-IC-socket area 1c.

Therefore, since a relay socket 4 is located just under each IC socket 2, the length of the wiring for coupling the IC socket 2 and the relay socket 4 is shortened.

As a result, as indicated by the waveform chart of FIG. 12 for the signal pin in the first embodiment, the voltage rises to the expected level in regions C and D of the chart. This is because due to the decreased wiring length, the wiring resistance and wiring capacitance are decreased. Since the voltage rises to the expected level, even in the case of a multiple parallel test board 1 on which a larger number of electronic components such as relays are mounted, its existing characteristics can be maintained.

Next, how the test board 1 copes with an increase in the number of DUTs (devices under test) to be measured (tested) at a time will be described by comparison between the first embodiment and the comparative example.

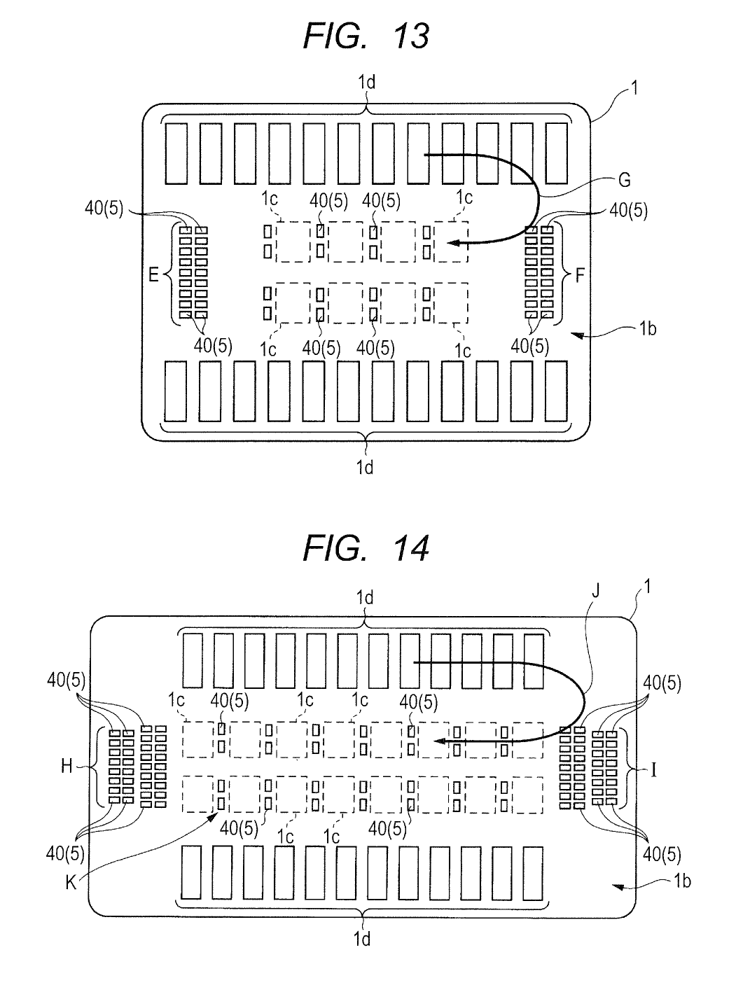

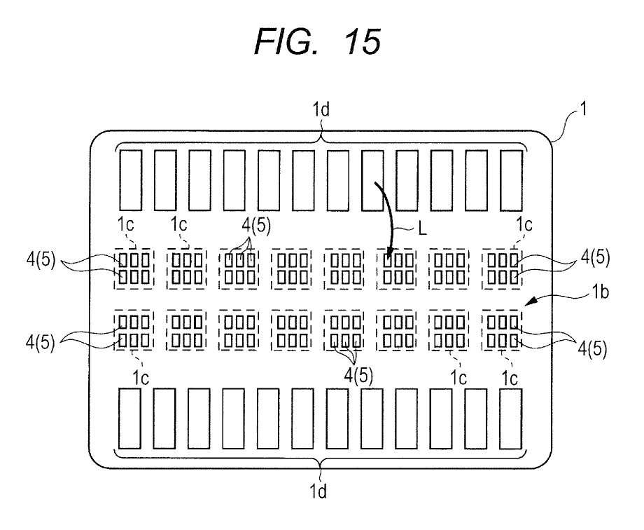

FIG. 13 is a back view illustrating an image of the wiring length of the test board in the comparative example, FIG. 14 is a back view illustrating an image of the wiring length of the test board in the comparative example, and FIG. 15 is a back view illustrating an image of the wiring length of the test board according to the first embodiment.

FIGS. 13 and 14 show a case that in the test board 1 in the comparative example, the number of DUTs is increased from 8 to 16, in which FIG. 13 shows that the number of DUTs is 8 and FIG. 14 shows that the number of DUTs is 16. The test board 1 shown in FIGS. 13 and 14 uses lead type relay sockets 40.

When the number of DUTs is 8, eight IC sockets 2 are arranged in 2 rows by 4 columns on the front surface 1a of the test board 1 as shown in FIG. 1 and eight under-IC-socket areas 1c are formed 2 rows by 4 columns in a manner to correspond to the sockets 2, as shown in FIG. 13.

However, since the lead type relay sockets 40 cannot be mounted in the under-IC-socket areas 1c, they are mostly located in areas away from the under-IC-socket areas 1c and the component mounting prohibition areas 1d as the pogo seat block areas (areas to be coupled to a test head 6 which will be described later), namely areas E and F.

Regarding the test board 1 in the comparative example shown in FIG. 13, the wiring for coupling the IC sockets 2 (see FIG. 1), the relay sockets 40 in area E or F, and the component mounting prohibition area 1d is expressed by image G, in which the size of the test board 1 is, for example, 468 mm by 390 mm.

When the number of DUTs is increased to 16 as shown in FIG. 14, the number of relay sockets 40 (relays 5) must be increased and in order to avoid the problem of shortage of the area for mounting the relay sockets 40, the size of the test board 1 is increased, for example, to 537 mm by 390 mm to obtain the area for mounting the relay sockets 40.

However, since the relay sockets 40 located in extension areas (H and I) have a tendency that the wiring from the component mounting prohibition area 1d (test head 6) to a device terminal is longer (wiring image J), the signal coupled to a device terminal through a relay socket 40 in an extension area is designed (arranged) in consideration of the influence of the type and frequency of the signal, etc. (including AC characteristics) on the test.

For example, the relay sockets 40 (relays 5) for terminals for lower frequency signals are located in area H and the relay sockets 40 (relays 5) for terminals for higher frequency signals are located in areas K adjacent to under-IC-socket areas 1c.

On the other hand, regarding the test board 1 according to the first embodiment shown in FIG. 15, the number of DUTs is 16 and its size is the same as the test board 1 shown in FIG. 13, namely 468 mm×390 mm.

Since surface mount relay sockets 4 are used, several relay sockets 4 are located in each of the under-IC-socket areas 1c of the back surface 1b of the test board 1.

Therefore, even when the size of the test board 1 is the same as the size of the test board 1 shown in FIG. 13, or 468 mm×390 mm, the number of DUTs to be measured at a time can be increased from 8 to 16.

Furthermore, as wiring image L in FIG. 15 indicates, the length of the wiring from the component mounting prohibition area 1d (test head 6) to a device terminal can be shortened and the electrical characteristics of the test board 1 can be improved.

Regarding the test board 1 shown in FIG. 15, the number of IC sockets 2 (see FIG. 2) on the front surface 1a is 16 and the IC sockets are arranged in 2 rows by 8 columns. Among the IC sockets arranged in 2 rows by 8 columns, the IC sockets (second IC sockets 2e in FIG. 2) located at the edges (corners) and the IC sockets (first IC sockets 2d) located between the second IC sockets 2d are different in terms of wiring routing easiness.

More specifically, among the 16 IC sockets 2, whereas routing of the wirings to the IC sockets (second IC sockets 2e in FIG. 2) located at the edges (corners) is relatively easy, the freedom in routing is smaller for the wirings to the IC sockets 2 (first IC sockets 2d in FIG. 2) located between the second IC sockets 2.

However, regarding the test board 1 according to the first embodiment shown in FIG. 15, the length of the wiring from the component mounting prohibition area 1d (test head 6) to the device terminal can be shortened so that routing of the wirings to the IC sockets 2 for which the freedom in routing is small can be made and the electrical characteristics of the test board 1 can be improved.

Next, the length of inner wiring of the test board 1 according to the first embodiment will be described in comparison with that of the test board 1 in the comparative example.

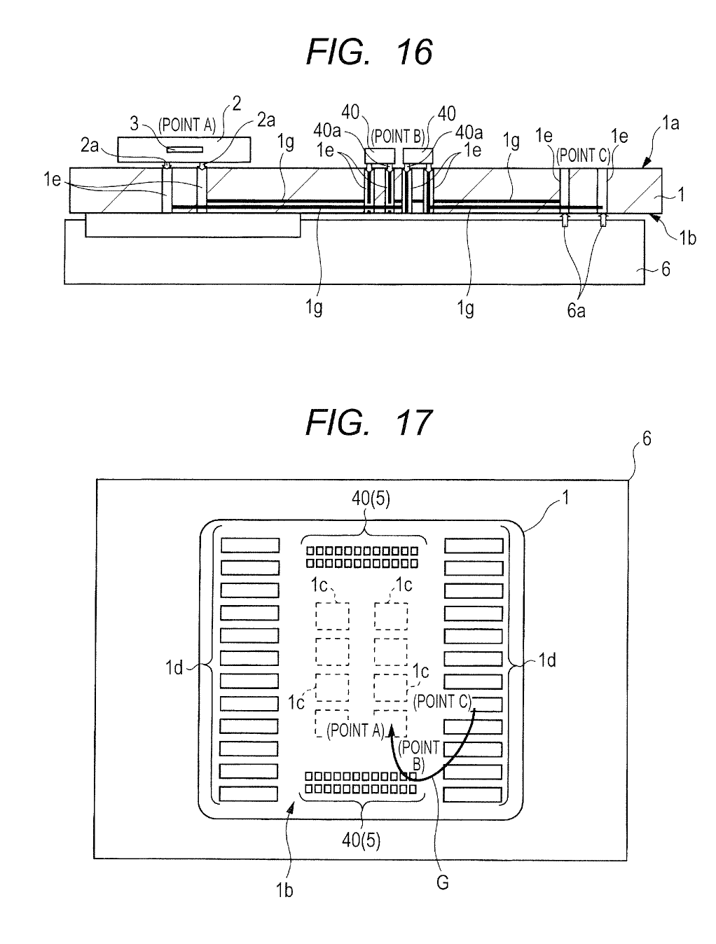

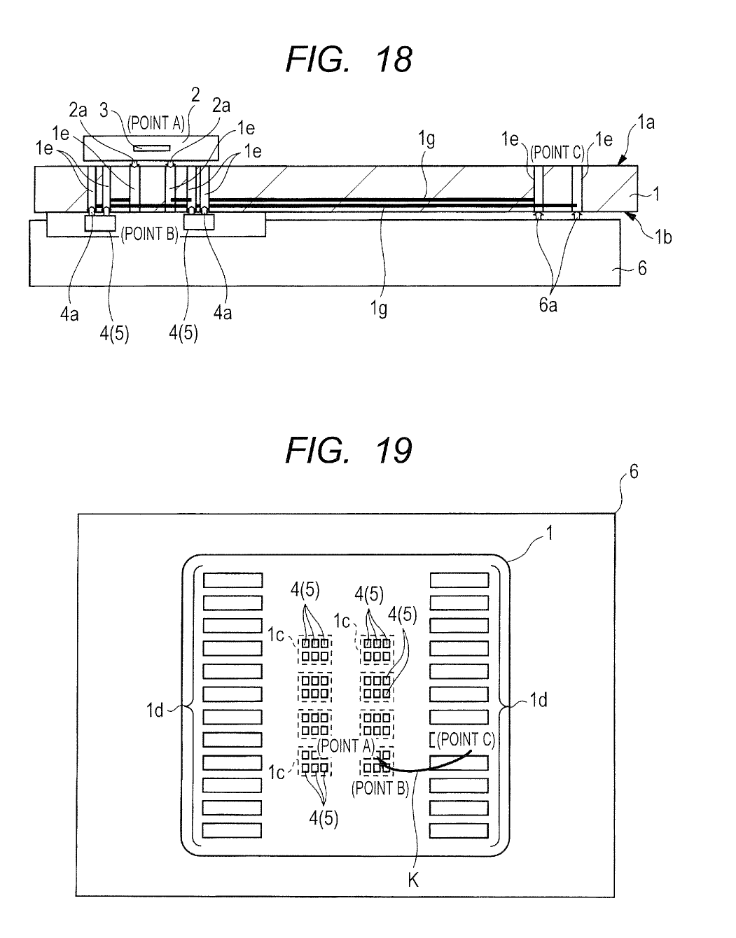

FIG. 16 is a sectional view showing an image of the wiring length of the test board in the comparative example which uses inner wirings, FIG. 17 is a plan view showing an image of the wiring length of the test board in the comparative example which uses inner wirings, FIG. 18 is a sectional view showing an image of the wiring length of the test board according to the first embodiment which uses inner wirings, and FIG. 19 is a plan view showing an image of the wiring length of the test board according to the first embodiment which uses inner wirings.

FIGS. 16 and 17 show the test board 1 in the comparative example which is mounted on the test head 6. As shown in FIG. 16, the relay sockets 40 are electrically coupled to the through-hole wirings 1e of the test board 1 via leads 40a. The test board 1 and the test head 6 are electrically coupled via the pogo pins 6a of the test head 6.

The terminals in the component mounting prohibition area 1d shown in FIG. 17, the relay sockets 40 (relays 5), and the IC sockets 2 are electrically coupled via the through-hole wirings 1e and inner wirings 1g.

FIG. 17 is a plan view showing how these are coupled. As the wiring image G in FIG. 17 indicates, the length of the wiring including the inner wirings 1g shown in FIG. 16 cannot be shortened. Specifically, in the plan view, the route of the inner wiring 1g is point A to point B to point C and these points are distant from each other, so the inner wiring 1g shown in FIG. 16 cannot be shortened.

In contrast, FIGS. 18 and 19 show the test board 1 according to the first embodiment which is mounted on the test head 6. As shown in FIG. 18, surface mount relay sockets 4 (relays 5) are mounted just under an IC socket 2. The relay sockets 4 are electrically coupled to through-hole wirings 1e of the test board 1 via bump electrodes 4a.

FIG. 19 is a plan view showing an image of wiring routing, suggesting that due to the use of surface mount relay sockets 4, the length of wiring including an inner wiring 1g is shortened. More specifically, since surface mount relay sockets 4 are used, the relay sockets 4 can be located just under the IC socket 2 and as a result, the route of the inner wiring 1g is point A to point B to point C as shown in FIG. 19. Since several relay sockets 4 (relays 5) are located under the IC socket 2, the wiring length between points A and B is very short.

Consequently, the wiring which couples the points A, B, and C shown in FIGS. 18 and 19 can be shortened.

Next, the method for testing (measuring) a semiconductor device using the test head 6 according to the first embodiment will be described.

First, a test board 1 is provided in which a plurality of IC sockets 2 are mounted on the front surface 1a and a plurality of surface mount relay sockets 4 to be electrically coupled to the IC sockets 2 are mounted on the back surface 1b, and the relay sockets 4 are mounted in a manner to overlap one of the IC sockets in a plan view. In short, a test board 1 with a plurality of relay sockets 4 mounted in the under-IC-socket areas 1c of the back surface 1b is provided.

After providing the test board, a semiconductor device 3 is placed in each of the IC sockets 2 and a relay 5 is attached to each of the relay sockets 4.

The test board 1 is mounted on the test head 6 and the test board 1 and the test head 6 are electrically coupled via the pogo pins 6a of the test head 6. A given signal for testing (measuring) the semiconductor device 3 placed in the IC socket 2 is transmitted from the test head 6 to the test board 1.

An IC socket 2 and the test board 1 are electrically coupled by a plurality of coupling terminals provided in the area for the IC socket 2 in a plan view. The coupling terminals are the pogo pins 2a of the IC socket 2 and the pogo seats 1f at the ends of the through-hole wirings 1e of the test board 1 as shown in FIG. 6.

As mentioned above, testing (measurement) is performed on each of the semiconductor devices 3 as prescribed while the IC sockets 2 housing semiconductor devices 3 are mounted on the front surface 1a of the test board 1 and the relay sockets 4 each housing a relay 5 are mounted just under the IC sockets 2 on the back surface 1b.

As discussed above, in the semiconductor device manufacturing (testing) method according to the first embodiment, since surface mount sockets are used as the relay sockets 4 mounted on the back surface 1b of the test board 1, the IC sockets 2 and relay sockets 4 can be arranged in a manner to overlap each other in a plan view. In other words, due to the use of surface mount sockets as the relay sockets 4, space is available under each IC socket 2 on the back surface 1b of the test board 1 and the relay sockets 4 are located in this space so that the length of the wiring coupling an IC socket 2 and a relay socket 4 can be shortened.

This suppresses the increase in the wiring resistance and wiring capacitance and prevents a voltage drop during testing (improves the characteristics of output waves). In addition, the yield can be improved.

Consequently, high quality testing can be performed on the semiconductor device 3.

Furthermore, stable high-quality characteristics are maintained even for a multiple parallel test board on which a larger number of components are mounted.

Next, a variation of the first embodiment will be described.

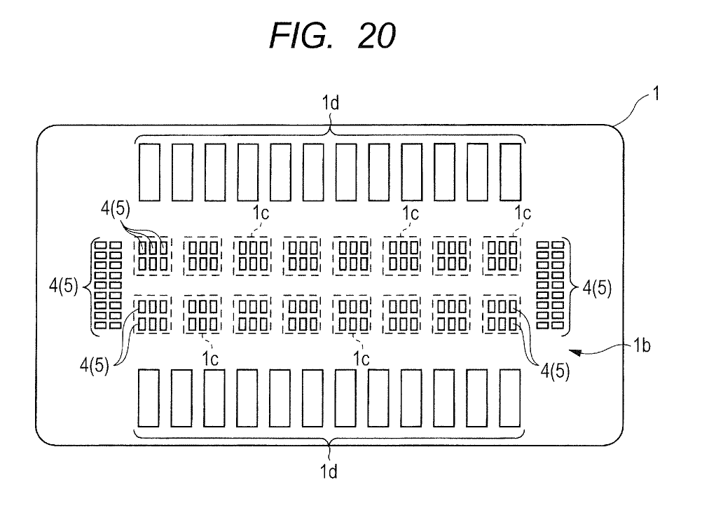

FIG. 20 is a back view of the test board as a variation of the first embodiment, showing the arrangement of relays. On the test board 1 shown in FIG. 20, some of the relay sockets 4 are mounted in peripheral areas of the back surface 1b of the test board 1.

For example, a plurality of relay sockets 4 which overflow from the areas just under IC sockets 2 are mounted in peripheral areas of the back surface 1b of the test board 1. In other words, all the relay sockets 4 need not be located just under the IC sockets 2 and some of the relay sockets 4 may be mounted in peripheral areas, etc. of the back surface 1b of the test board 1.

This variation also brings about the same advantageous effects as the test board 1 according to the first embodiment shown in FIG. 1.

### Second Embodiment

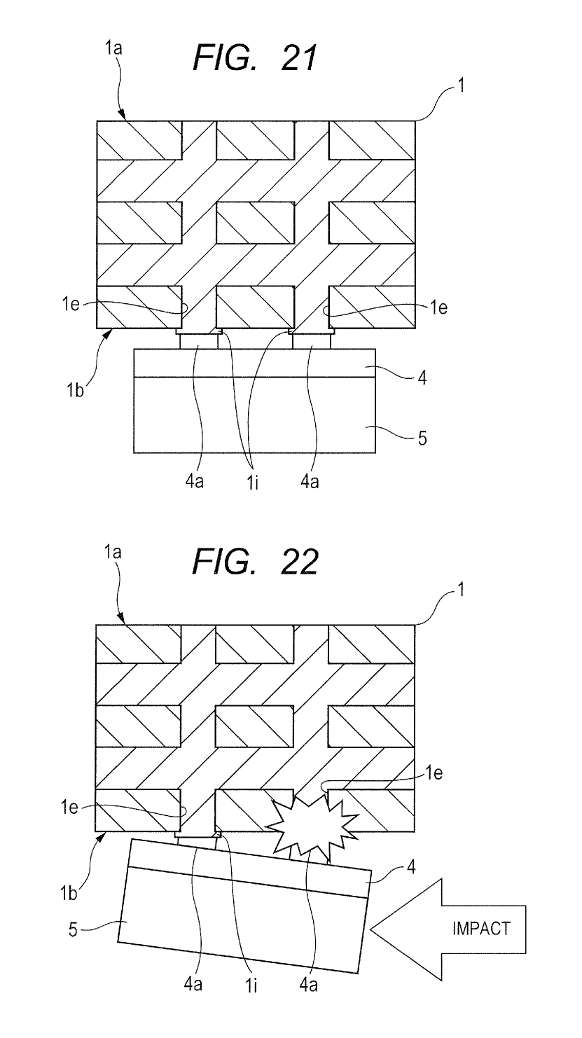

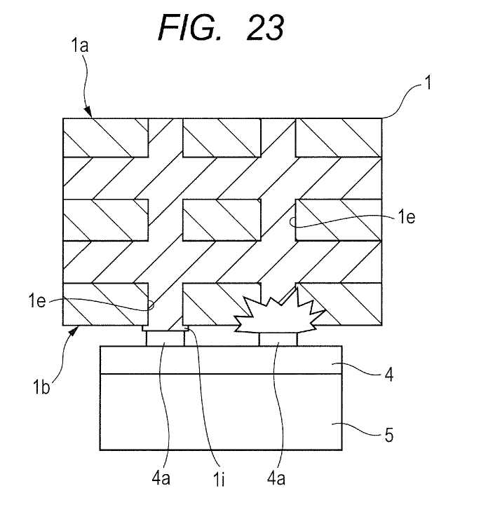

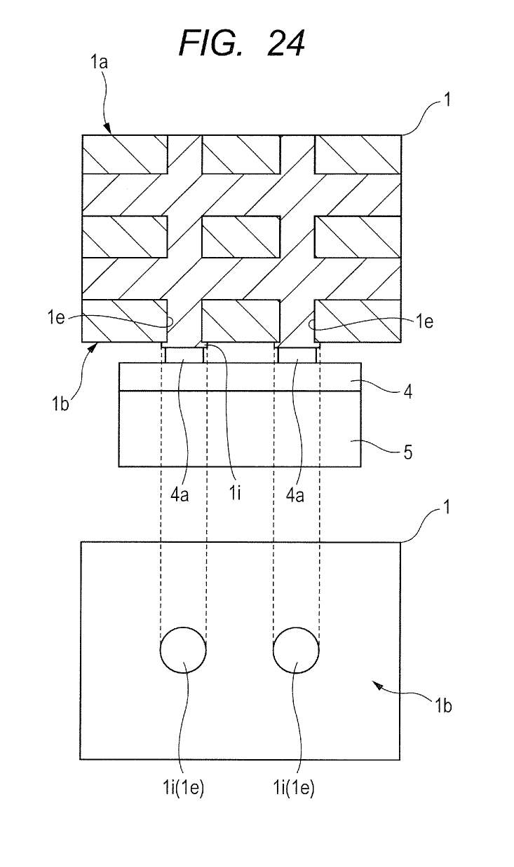

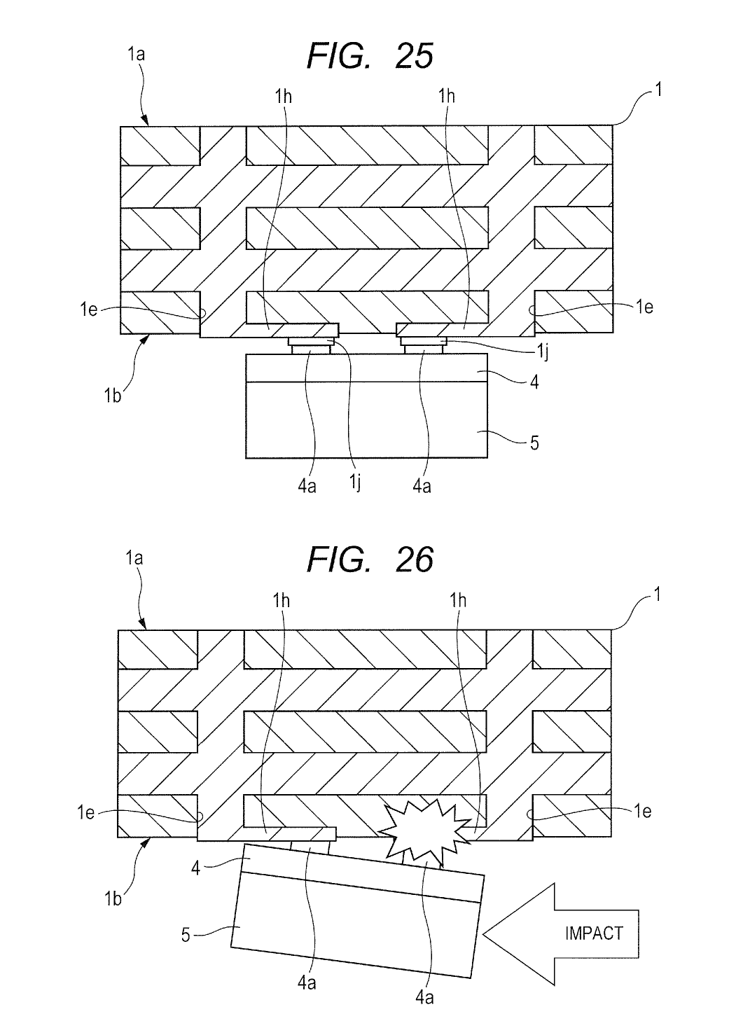

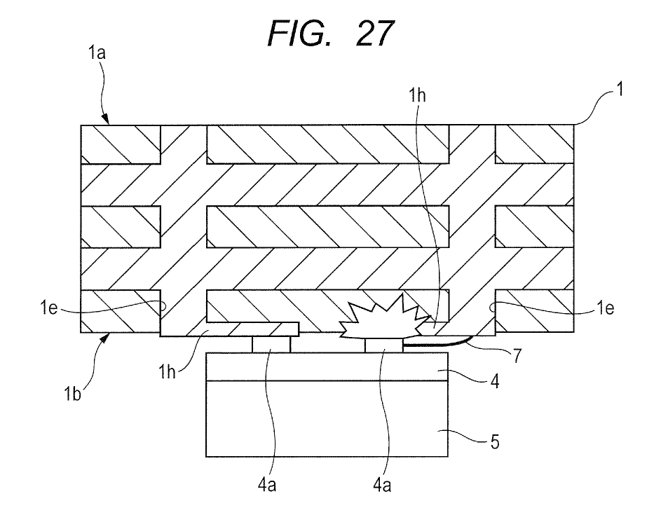

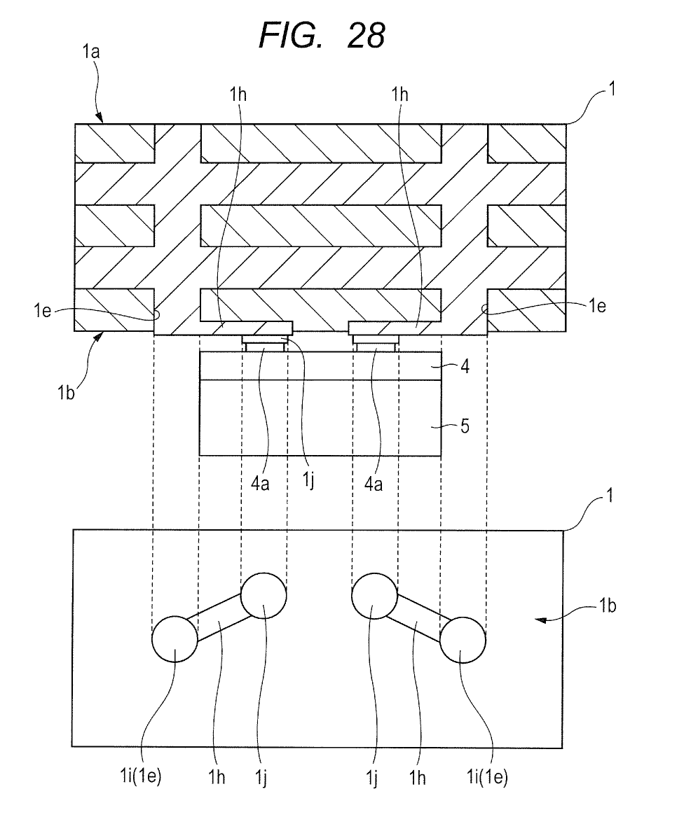

FIG. 21 is a sectional view showing how a relay socket is mounted in a comparative example, FIG. 22 is a sectional view showing how the relay socket in the comparative example receives an impact, FIG. 23 is a sectional view showing the relay socket in the comparative example which cannot be repaired, and FIG. 24 is a sectional view with a back view, showing the form of a land of the test board in the comparative example. FIG. 25 is a sectional view showing how a relay socket is mounted in the second embodiment, FIG. 26 is a sectional view showing how the relay socket in the second embodiment receives an impact, FIG. 27 is a sectional view showing how the relay socket in the second embodiment is repaired, and FIG. 28 is a sectional view with a back view, showing the form of a land of the test board in the second embodiment.

The second embodiment concerns the form of a land for coupling a relay socket 4 on the back surface 1b of the test board 1.

In the comparative example shown in FIG. 21, a surface mount relay socket 4 is mounted just under a through-hole wiring 1e. As shown in FIG. 24, in the comparative example, the exposed portions of the through-hole wirings 1e are lands 1i and the relay socket 4 is coupled to the lands 1i as shown in FIG. 21.

In the comparative example, if an impact is given to the relay socket 4 sideways as shown in FIG. 22, the relay socket 4 may come off the test board 1. If the relay socket 4 comes off, the land 1i concerned also comes off the test board 1. Consequently, the land is peeled off and removed from the test board 1, making it impossible to repair the test board 1. As a result, there arises a problem that the test board 1 must be remade and the test cost increases.

As a solution to this problem, according to the second embodiment, the lands of the test board 1 are formed as shown in FIG. 28: namely a land 1j electrically coupled to a through-hole wiring 1e is located away from the through-hole wiring 1e on the back surface 1b of the test board 1 in a plan view. More specifically, the land 1j is formed on a lead-out wiring 1h from the through-hole wiring 1e, and the through-hole wiring 1e and the land 1j do not overlap in a plan view.

As shown in FIG. 25, a relay socket 4 mounted in a manner to overlap one of the IC sockets 2 (see FIG. 2) in a plan view is electrically coupled to a land 1j.

If an impact is given to the relay socket 4 sideways as shown in FIG. 26, the relay socket 4 may come off the test board 1 as in the comparative example shown in FIG. 22. If the relay socket 4 comes off, the land 1j shown in FIG. 25 also comes off the test board 1 and as in the comparative example shown in FIG. 23, the land for mounting is peeled off and removed from the test board 1.

However, since the through-hole wiring 1e remains intact, the test board 1 can be repaired by electrically coupling the through-hole wiring 1e and the bump electrode 4a of the relay socket 4 by a conductive member, as shown in FIG. 27. Specifically, after the test board 1 with a surface mount relay socket 4 mounted on the back surface 1b as shown in FIG. 25 is provided, if an impact is given to the relay socket 4 and the land 1j comes off together with the relay socket 4 as shown in FIG. 26, the exposed through-hole wiring 1e on the back surface 1b of the test board 1 and the bump electrode 4a of the relay socket 4 are electrically coupled by the conductive member as shown in FIG. 27.

The test board 1 is thus repaired.

The semiconductor device 3 is tested while the through-hole wiring 1e and the bump electrode 4a of the relay socket 4 are electrically coupled by the conductive member.

In this case, it is unnecessary to remake the test board 1, so the test cost can be reduced.

The conductive member which electrically couples the through-hole wiring 1e and the bump electrode 4a of the relay socket 4 is, for example, a lead wire 7, or it may be a metal wire.

In the semiconductor device manufacturing method according to the second embodiment, the land 1j electrically coupled to the through-hole wiring 1e is located away from the through-hole wiring 1e of the test board 1 on the back surface 1b of the test board 1 and the relay socket 4 mounted in a manner to overlap the IC socket 2 in a plan view is coupled to the land 1j. Therefore, even if the area for mounting the relay socket 4 (for example, the land 1j) is damaged, the relay socket 4 and the through-hole wiring 1e can be coupled again by a lead wire 7 or the like. This means that the test board 1 can be repaired and the number of times of remaking the test board 1 can be decreased. As a result, the cost of testing (measuring) the semiconductor device 3 can be reduced.

The test board 1 according to the second embodiment shown in FIGS. 25 to 28 also brings about the same advantageous effects as the test board 1 according to the first embodiment. Since surface mount sockets are used as the relay sockets 4 mounted on the back surface 1b of the test board 1, an IC socket 2 and a relay socket 4 can be located in a manner to overlap each other in a plan view. Therefore, the length of the wiring for coupling the IC socket 2 and the relay socket 4 can be shortened.

This suppresses the increase in the wiring resistance and wiring capacitance and prevents a voltage drop during testing. Consequently high quality testing can be performed on the semiconductor device 3.

The invention made by the present inventors has been so far explained concretely in reference to the preferred embodiments thereof. However, the invention is not limited thereto and it is obvious that these details may be modified in various ways without departing from the gist thereof.

For example, the first embodiment has been described above on the assumption that six relay sockets 4 are mounted in an under-IC-socket area 1c corresponding to an IC socket 2. However, the number of relay sockets 4 mounted in one under-IC-socket area 1c is not limited to 6 but it may be any number that is 1 or 2 or more.

The first and second embodiments have been described above on the assumption that the electronic component mounted on the back surface 1b of the test board 1 is a relay 5 and the electronic component socket is a relay socket 4. However, the electronic component may be any electronic component other than the relay 5 and the socket may be not the relay socket 4 but a socket for housing the other electronic component.

What is claimed is:

1. A semiconductor device manufacturing method comprising the steps of:
(a) providing a test board having a first surface and a second surface opposite to the first surface, in which a plurality of IC sockets are mounted on the first surface and a plurality of surface mount electronic component sockets to be electrically coupled to the IC sockets are mounted on the second surface; and
(b) placing semiconductor devices in the IC sockets and performing a test on the semiconductor devices with electronic components attached to the electronic component sockets,
wherein the IC socket and the test board are electrically coupled by a plurality of coupling terminals provided in an area for the IC socket in a plan view, and
wherein some of the electronic component sockets are mounted in a manner to overlap some of the IC sockets in a plan view.

2. The semiconductor device manufacturing method according to claim 1,
wherein the electronic component is a relay, the electronic component socket is a relay socket, and the relay sockets are mounted on the second surface of the test board, and
wherein at the step (b), the test is performed on the semiconductor devices with the relay attached to each of the relay sockets.

3. The semiconductor device manufacturing method according to claim 1, wherein each of the IC sockets is mounted on the test board in an attachable/detachable manner.

4. The semiconductor device manufacturing method according to claim 2, wherein each of the relay sockets is soldered onto a terminal of the test board.

5. The semiconductor device manufacturing method according to claim 2, wherein the relay sockets are mounted on the second surface in a manner to overlap the IC sockets in a plan view.

6. The semiconductor device manufacturing method according to claim 2, wherein some of the relay sockets are mounted in a peripheral area of the second surface of the test board.

7. The semiconductor device manufacturing method according to claim 2,
wherein the IC sockets include first IC sockets and second IC sockets and are arranged in a matrix pattern, and
wherein the second IC sockets are mounted on both sides of the first IC sockets.

8. The semiconductor device manufacturing method according to claim 2, wherein the IC sockets and the relay sockets are electrically coupled via through-hole wirings of the test board.

9. A semiconductor device manufacturing method comprising the steps of:
(a) providing a test board having a first surface and a second surface opposite to the first surface, in which a plurality of IC sockets are mounted on the first surface and a plurality of surface mount electronic component sockets to be electrically coupled to the IC sockets via through-hole wirings are mounted on the second surface; and
(b) placing semiconductor devices in the IC sockets and performing a test on the semiconductor devices with electronic components attached to the electronic component sockets,
wherein the IC socket and the test board are electrically coupled by a plurality of coupling terminals provided in an area for the IC socket in a plan view,
wherein some of the electronic component sockets are mounted in a manner to overlap some of the IC sockets in a plan view,
wherein a land electrically coupled to the through-hole wiring is formed away from the through-hole wiring on the second surface in a plan view, and
wherein the electronic component socket mounted in a manner to overlap some of the IC sockets in a plan view is electrically coupled to the land.

10. The semiconductor device manufacturing method according to claim 9,
wherein the electronic component is a relay, the electronic component socket is a relay socket, and the relay sockets are mounted on the second surface of the test board, and
wherein at the step (b), the test is performed on the semiconductor devices with the relay attached to each of the relay sockets.

11. The semiconductor device manufacturing method according to claim 9, wherein each of the IC sockets is mounted on the test board in an attachable/detachable manner.

12. The semiconductor device manufacturing method according to claim 10, wherein each of the relay sockets is soldered onto a terminal of the test board.

13. The semiconductor device manufacturing method according to claim 10, wherein the relay sockets are mounted on the second surface in a manner to overlap the IC sockets in a plan view.

14. The semiconductor device manufacturing method according to claim 9,
wherein the IC sockets include first IC sockets and second IC sockets and are arranged in a matrix pattern, and
wherein the second IC sockets are mounted on both sides of the first IC sockets.

15. The semiconductor device manufacturing method according to claim 9,
wherein the electronic component is a relay and the electronic component socket is a relay socket, and after the step (a) the method comprises the step of electrically coupling the through-hole wiring exposed on the second surface of the test board and an electrode of the relay socket by a conductive member, and
wherein the test at the step (b) is performed while the through-hole wiring and the electrode of the relay socket are electrically coupled by the conductive member.
